(19) United States
(12) Patent Application Publication
(10) Pub. No.: US 2006/0177999 A1
(43) Pub. Date: Aug. 10, 2006

(54) Microelectronic workpieces and methods for forming interconnects in microelectronic workpieces

(75) Inventors: David R. Hembree, Boise, ID (US); Charles M. Watkins, Eagle, ID (US); Kyle K. Kirby, Boise, ID (US); Steven D. Oliver, Boise, ID (US); Salman Akram, Boise, ID (US); Sidney B. Rigg, Meridian, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/056,211

(22) Filed: Feb. 10, 2005

(51) Int. Cl. H01L 21/44

(52) U.S. Cl. 438/597; 438/687

(57) ABSTRACT

Methods for forming interconnects in blind holes and microelectronic workpieces having such interconnects are disclosed herein. One aspect of the invention is directed toward a method for manufacturing a microelectronic workpiece having microelectronic dies with integrated circuits and terminals electrically coupled to the integrated circuits. In one embodiment, the method includes forming a blind hole in the workpiece. The blind hole extends from a first exterior side of the workpiece to an intermediate depth in the workpiece. The method continues by forming a vent in the workpiece. The vent is in fluid communication with the blind hole. The method further includes constructing an electrically conductive interconnect in at least a portion of the blind hole.

### TECHNICAL FIELD

The present invention relates to forming interconnects in microelectronic workpieces and microelectronic workpieces formed using such methods.

### BACKGROUND

Microelectronic devices, micromechanical devices, and other devices with microfeatures are typically formed by constructing several layers of components on a workpiece. In the case of microelectronic devices, a plurality of dies are fabricated on a single workpiece, and each die generally includes an integrated circuit and a plurality of bond-pads coupled to the integrated circuit. The dies are separated from each other and packaged to form individual microelectronic devices that can be attached to modules or installed in other products.

One aspect of fabricating and packaging such dies is forming interconnects that electrically couple conductive components located in different layers. In some applications, it may be desirable to form interconnects that extend completely through the dies or through a significant portion of the dies. Such interconnects electrically couple bond-pads or other conductive elements proximate to one side of the dies to conductive elements proximate to the other side of the dies. Through-wafer interconnects, for example, are constructed by forming deep vias on the front side and/or backside of the wafer and in alignment with bond-pads at the front side of the wafer. The vias are often blind vias in that they are closed at one end. The blind vias are then filled with a conductive fill material. After further processing the wafer, it is eventually thinned to reduce the thickness of the final dies. Solder balls or other external electrical contacts are subsequently attached to the through-wafer interconnects at the backside and/or the front side of the wafer. The solder balls or external contacts can be attached either before or after singulating the dies from the wafer.

One concern of forming through-wafer interconnects is that it is difficult to fill deep, narrow blind vias with electrically conductive material. In most processes using solder, for example, flux is used on a layer of nickel within the blind via to remove oxides from the nickel and to prevent the nickel and other materials in the via (e.g., solder) from forming oxides. When the molten solder enters the blind via, the flux solvent produces gases that can be trapped in the closed end of the blind via. This is problematic because the gases may produce voids or other discontinuities in the interconnect. In addition, the flux itself may be trapped in the fill material and cause additional voids or irregular regions within the interconnect.

Another concern of forming through-wafer interconnects using blind vias is that vapor deposition processes may produce non-uniform seed layers on the sidewalls in the vias. This can affect subsequent plating processes in high aspect ratio holes because the nonuniform seed layers cause the plating rate to be higher at the openings than deep within the vias. The electroplating processes, for example, may “pinch-off” the openings of high aspect ratio holes before the holes are filled completely. Therefore, there is a need to more effectively form interconnects in blind vias and other deep holes in microfeature workpieces.

### BRIEF DESCRIPTION OF THE DRAWINGS

FIGS. 1A-1K are side cross-sectional views illustrating a portion of a workpiece at stages of a method for forming interconnects in accordance with an embodiment of the invention.

FIG. 2 is a side cross-sectional view of a portion of a workpiece illustrating a stage of a method for depositing conductive fill material into a blind hole accordance with another embodiment of the invention.

FIGS. 3A-3C are side cross-sectional views of a portion of a workpiece illustrating stages of a method for depositing conductive fill material into a blind hole in accordance with yet another embodiment of the invention.

FIG. 4 is a side cross-sectional view of a portion of a workpiece illustrating a stage of a method for forming interconnects in accordance with still another embodiment of the invention.

FIG. 5 is a side cross-sectional view of a portion of a workpiece illustrating a stage of a method for forming interconnects in accordance with yet another embodiment of the invention.

### DETAILED DESCRIPTION

A. Overview

The following disclosure describes several embodiments of methods for forming interconnects in blind holes, and microelectronic workpieces having such interconnects. One aspect of the invention is directed toward a method for manufacturing a microelectronic workpiece having microelectronic dies with integrated circuits and terminals electrically coupled to the integrated circuits. In one embodiment, the method includes forming a blind hole in the workpiece. The blind hole extends from a first exterior side of the workpiece to an intermediate depth in the workpiece. The method continues by forming a vent in the workpiece. The vent extends to the blind hole such that gases or other fluids can flow from the blind hole to the vent. The vent can accordingly be in fluid communication with the blind hole. The method further includes constructing an electrically conductive interconnect in at least a portion of the blind hole. The method can then include removing material from a second exterior side of the workpiece to thin the workpiece.

Before forming the vent, the method can also include applying a dielectric liner to at least a portion of the blind hole, depositing a barrier layer over at least a portion of the dielectric liner, and depositing a seed layer onto the barrier layer. A layer of resist is then deposited over the workpiece and an opening is formed in the resist over the blind hole. A conductive material is then deposited into the blind hole and over at least a portion of the seed layer. The conductive layer can act as a wetting agent for a conductive fill material that is deposited into the blind hole to form the interconnect after forming the vent.

Another aspect of the invention is directed toward a microelectronic assembly including microfeature workpiece having a substrate with a first side and a second side. The assembly can include a microelectronic die on and/or in the substrate. The die includes an integrated circuit and a terminal electrically coupled to the integrated circuit. The assembly can also include a blind hole in the substrate extending from the first side of the substrate to an endpoint at an intermediate depth within the substrate. The assembly also includes a vent hole in the workpiece that is open to the blind hole and an electrically conductive interconnect in at least a portion of the blind hole.

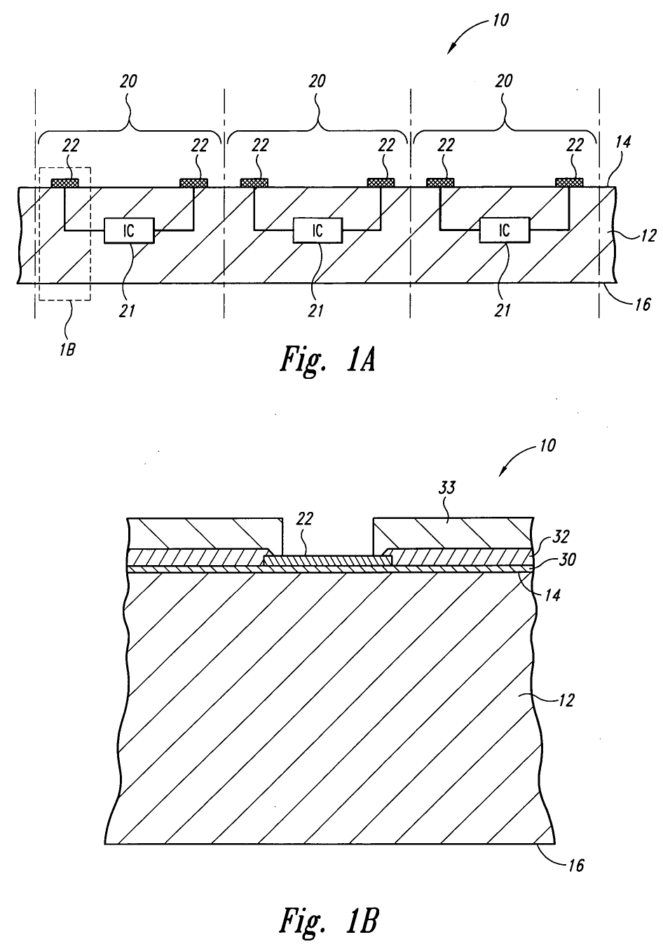

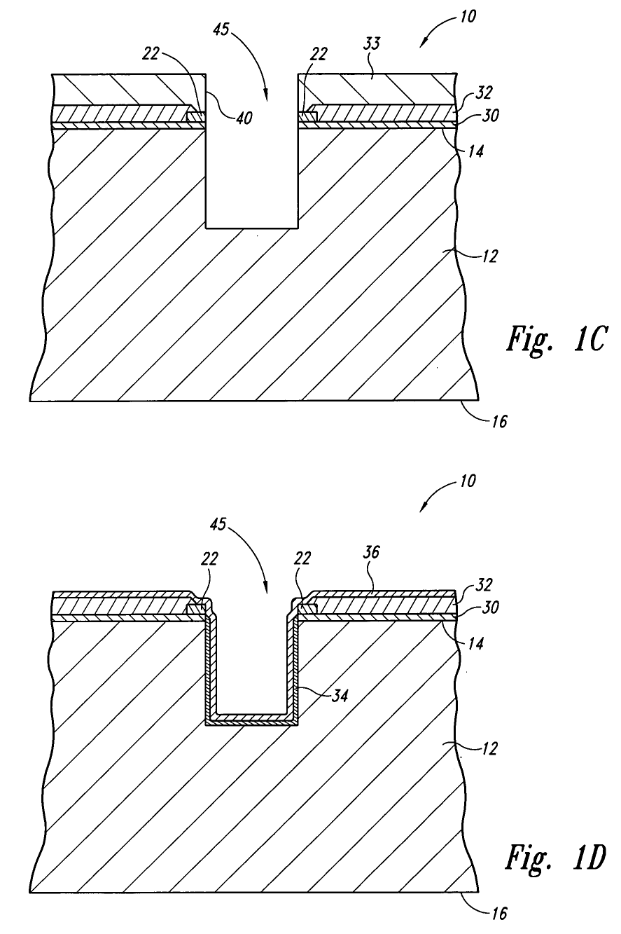

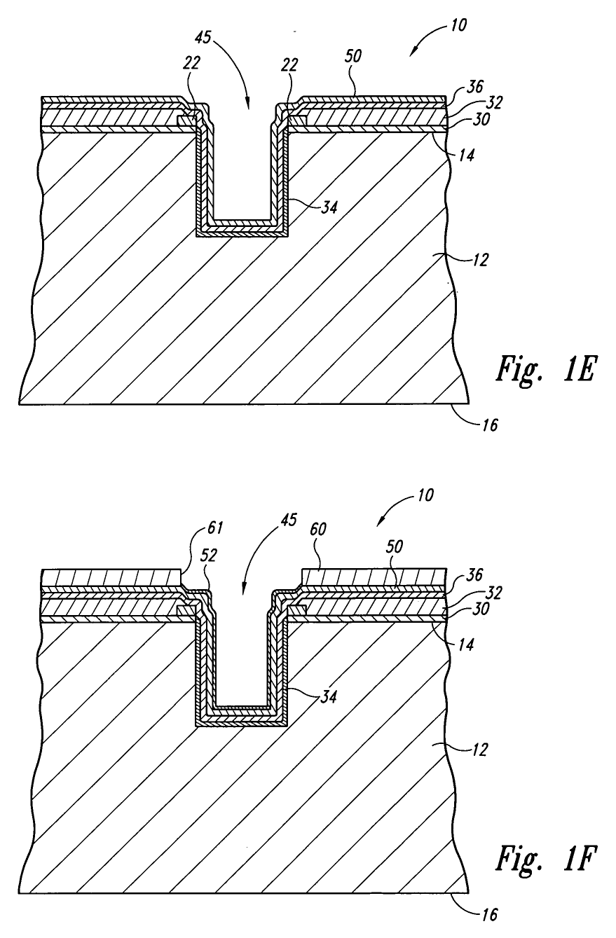

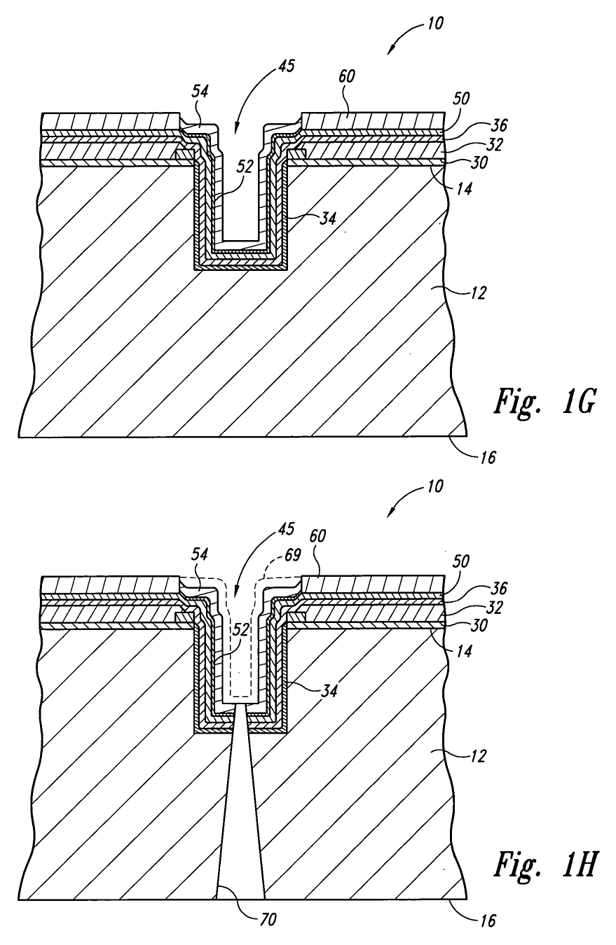

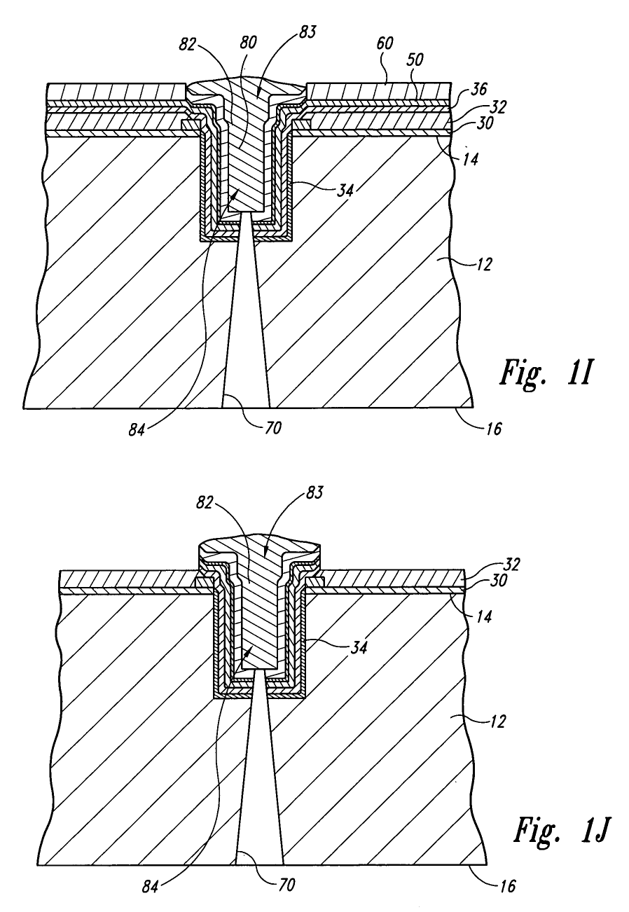

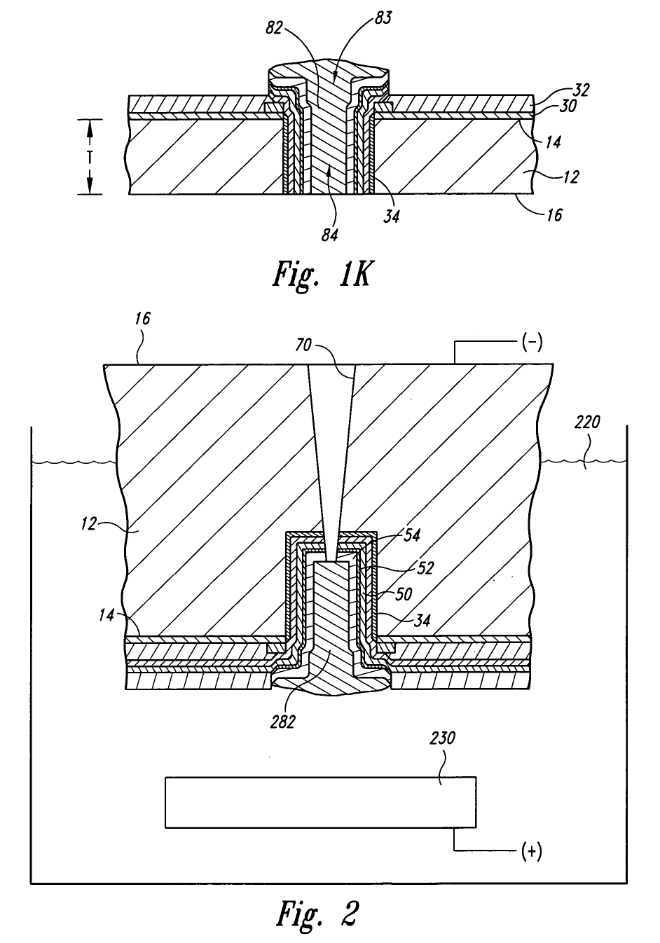

Specific details of several embodiments of the invention are described below with reference to interconnects extending from a terminal proximate to the front side of a workpiece, but the methods and workpieces described below can be used for other types of interconnects within microelectronic workpieces. Several details describing well-known structures or processes often associated with fabricating microelectronic devices are not set forth in the following description for purposes of clarity. Also, several other embodiments of the invention can have different configurations, components, or procedures than those described in this section. A person of ordinary skill in the art, therefore, will accordingly understand that the invention may have other embodiments with additional elements, or the invention may have other embodiments without several of the elements shown and described below with reference to FIGS. 1A-5.

B. Methods of Forming Interconnects in Microelectronic Workpieces

FIGS. 1A-1K illustrate various stages of a method for forming interconnects in a workpiece 10 in accordance with an embodiment of the invention. FIG. 1A illustrates the workpiece 10 at an initial stage before the interconnects have been formed. The workpiece 10 can include a substrate 12 having a first side 14 and a second side 16. The workpiece 10 can also include a plurality of microelectronic dies 20 on and/or in the substrate 12. Each microelectronic die 20 can include integrated circuitry 21 and a plurality of terminals 22 (e.g., bond-pads) operatively coupled to the integrated circuitry 21. The terminals 22 shown in FIG. 1A are external features at the first side 14 of the substrate 12. In other embodiments, however, the terminals 22 can be internal features that are embedded at an intermediate depth within the substrate 12.

FIG. 1B is a side cross-sectional view of the area 1B shown in FIG. 1A. In previous processing steps, a first dielectric layer 30 was applied to the first side 14 of the substrate 12, and a second dielectric layer 32 was applied over the first dielectric layer 30. The second dielectric layer 32 was then patterned and etched to expose the terminal 22. The dielectric layers 30 and 32 can be a polyimide material, but these dielectric layers can be other nonconductive materials in other embodiments. For example, the first dielectric layer 30 and/or one or more of the subsequent dielectric layers can be parylene, a low temperature chemical vapor deposition (low temperature CVD) material such as tetraethylorthosilicate (TEOS), silicon nitride (Si₃N₄), and silicon oxide (SiO₂), and/or other suitable materials. The foregoing list of dielectric materials is not exhaustive. The dielectric layers 30 and 32 are not generally composed of the same material as each other, but these layers may be composed of the same material. In addition, one or both of the layers 30 and 32 may be omitted and/or additional layers may be included, such as in the case of a redistribution layer. After depositing the second dielectric layer 32, a mask 33 is applied over the second dielectric layer 32 and patterned as shown in FIG. 1B. The mask 33 can be a layer of resist that is patterned according to the arrangement of terminals 22 on the substrate 12. As such, the mask 33 has an opening over the terminal 22.

Referring to FIG. 1C, a hole or aperture 40 is formed through at least part of the substrate 12. The hole 40 extends through the terminal 22, the first dielectric layer 30, and a portion of the substrate 12 to define a blind hole or via 45. For purposes of this specification, a “blind hole” or “blind via” refers to a hole or aperture that extends only partially through the substrate 12 or is otherwise closed at one end. The hole 40 is formed by etching through the materials using one or more individual etches. After forming the hole 40, the mask 33 is removed from the workpiece 10.

The hole 40 can alternatively be formed using a laser in addition to or in lieu of etching. If a laser is used to form all or a portion of the hole 40, it is typically cleaned using chemical cleaning agents to remove slag or other contaminants. Although laser cutting the hole 40 may be advantageous because the substrate 12 does not need to be patterned (i.e., mask 33 would not need to be applied), etching the hole 40 may be easier because the slag does not need to be cleaned from the hole 40 and the depth of the hole 40 can be more precisely controlled with an etching process. A further advantage of using an etching process is that the first side 14 of the substrate 12 can be patterned and etched to simultaneously form a plurality of holes 40 aligned with corresponding terminals 22. Furthermore, the holes 40 can generally be more precisely aligned using an etching process as compared with a laser cutting process.

Referring next to FIG. 1D, a third dielectric layer 34 is deposited onto the workpiece 10 to line the sidewalls of the hole 40 within the substrate 12. The third dielectric layer 34 electrically insulates components in the substrate 12 from an interconnect that is subsequently formed in the hole 40, as described in greater detail below. In one embodiment, the third dielectric layer 34 can be a low temperature CVD oxide, but in other embodiments the third dielectric layer 34 can be other suitable dielectric materials. A suitable etching process is then used to remove the third dielectric layer 34 from at least a portion of the terminal 22. A barrier layer 36 is then deposited onto the workpiece 10 over the third dielectric layer 34 and in electrical contact with the terminal 22. In practice, the barrier layer 36 generally covers the second dielectric layer 32 and the terminal 22 in addition to the third dielectric layer 34. The barrier layer 36 can be deposited onto the workpiece 10 using a vapor deposition process, such as CVD or physical vapor deposition (PVD). The barrier layer 36 can be composed of Ta, W, or other suitable materials.

Referring next to FIG. 1E, a seed layer 50 is deposited onto the barrier layer 36. The seed layer 50 can be deposited using vapor deposition techniques, such as CVD, PVD, atomic layer deposition, and/or plating. The seed layer 50 can be composed of Cu or other suitable materials. The thickness of the seed layer 50 is generally 400 Angstroms to 2 microns. The seed layer 50, however, may not cover the barrier layer 36 uniformly. This may cause subsequent electroplating processes to not apply a uniform metal layer onto the workpiece. If the seed layer is deficient, it can be enhanced using an enhancement process that fills voids or noncontinuous regions of the seed layer 50 to form a more uniform seed layer. One suitable seed layer enhancement process is described in U.S. Pat. No. 6,197,181, which is incorporated by reference.

Referring next to FIG. 1F, a resist layer 60 is deposited onto the seed layer 50, and the resist layer 60 is patterned to have an opening 61 over the terminal 22 and corresponding blind hole 45. In several embodiments, a first conductive layer 52 can then be deposited onto the exposed portions of the seed layer 50 in the blind hole 45. The first conductive layer 52 can be Cu that is deposited onto the seed layer 50 in an electroless plating operation, electroplating operation, or another suitable method. The application of the first conductive layer 52 is an optional step that can be omitted in several embodiments.

Referring to FIG. 1G, a second conductive layer 54 is deposited onto the first conductive layer 52 in the blind hole 45. The second conductive layer 54 is a wetting agent that facilitates depositing subsequent materials into the blind hole 45. The second conductive layer 54 can be Ni that is deposited onto the first conductive layer 52 using an electroless or electrolytic plating process. In other embodiments, the blind hole 45 may be coated with other suitable materials using other methods.

Referring next to FIG. 1H, a vent hole 70 is formed in the substrate 12 extending from a bottom portion of the blind hole 45 to the second side 16 of the substrate 12. The vent hole 70 can be formed using a laser to cut through the substrate 12 from the second side 16 to the bottom of the blind hole 45. The laser can be aligned with the blind hole 45 and/or corresponding terminal 22 using scanning/alignment systems known in the art. A suitable laser is the Xise200 commercially available from Xsil Ltd. of Dublin, Ireland. After forming the vent hole 70, it is generally cleaned to remove ablated byproducts (i.e., slag) and/or other undesirable byproducts resulting from the laser. For example, the vent hole 70 can be cleaned using a suitable cleaning agent, such as 6% tetramethylammonium hydroxide (TMAH): propylene glycol. In other embodiments, the vent hole 70 may not be cleaned. In alternative embodiments, the vent hole 70 can be a different size or shape, and may be formed using an etching process (e.g., a dry etch and/or a wet etch), a mechanical drilling process, a dicing or laser slot, or another suitable method.

In several embodiments, a temporary protective filling or coating 69 (shown in broken lines) can be deposited into the blind hole 45 before forming the vent hole 70. The protective filling 69 can be a photoresist, polymer, water, a solidified liquid or gas, or another suitable material. The protective filling 69 protects the sidewalls of the blind hole 45 from slag produced during the laser drilling process. The slag can negatively affect the plating of nickel onto the seed layer and/or the wetting of a conductive fill material into the blind hole 45. The protective filling 69 can be removed after forming the vent hole 70.

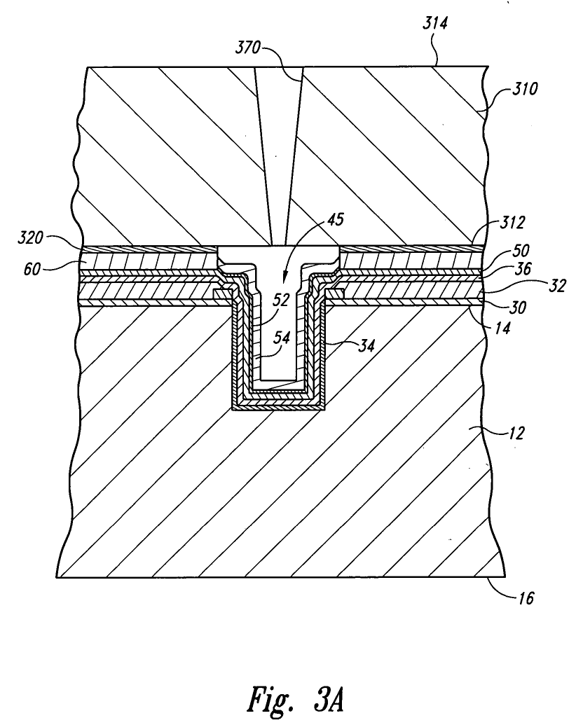

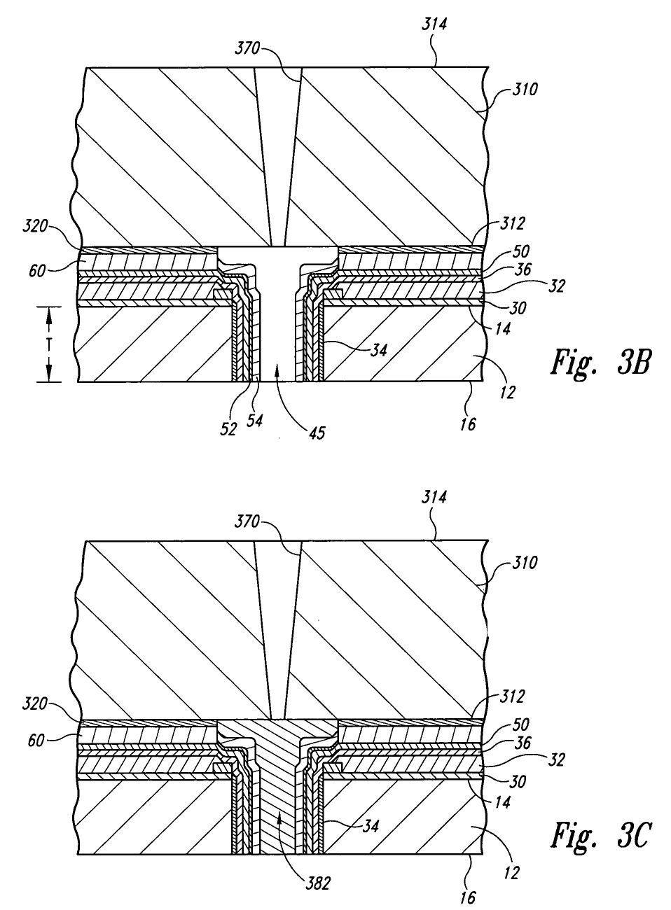

Referring next to FIG. 1I, a conductive fill material 80 is deposited into the blind hole 45 to form an interconnect 82. The interconnect 82 has a first end 83 proximate to the terminal 22 and a second end 84 at the bottom of the blind hole 45. The fill material 80 can include Cu, Ni, Co, Ag, Au, solder, or other suitable materials or alloys of materials having the desired conductivity. The conductive fill material 80 can be deposited into the blind hole 45 using plating processes, solder wave processes, screen printing processes, reflow processes, vapor deposition processes, or other suitable techniques. The plating processes, for example, can be electroless plating processes or electroplating processes. Several additional embodiments of methods for depositing the fill material 80 into the blind hole 45 are described below with respect to FIGS. 2-3C.

Referring to FIG. 1J, the resist layer 60 is removed from the workpiece 10 and a suitable etching process is used to remove the remaining portions of the seed layer 50 and barrier layer 36 on first side 14 of the substrate 12. Referring to FIG. 1K, the substrate 12 is thinned to a desired thickness “T” by removing material from the second side 16 of the substrate 12. In the illustrated embodiment, the second end 84 of the interconnect 82 is exposed after removing material from the second side 16. In one embodiment, the initial thickness of the substrate 12 is approximately 750 μm, and the final thickness T is approximately 100-500 μm. The initial and final thicknesses can be different in other embodiments. The second side 16 of the substrate 12 can be thinned using grinding, dry etching, chemical etching, chemical polishing, chemical mechanical planarization (CMP), or other suitable processes.

One advantage of several embodiments of the method for forming interconnects 82 illustrated in FIGS. 1A-1K is that the vent hole 70 allows trapped air, gases, or volatile solvents to escape from the larger blind hole 45 when filling the blind hole with the fill material 80. In this way, the vent hole 70 allows the fill material 80 to more easily flow into the blind hole 45 and mitigates the likelihood of voids or discontinuities in the interconnect 82.

Another advantage of several of the embodiments of the method described above in FIGS. 1A-1K is that the vent hole 70 will not become plugged while depositing the fill material 80 into the blind hole 45. Because the vent hole 70 is formed after depositing the second conductive layer 54, the fill material 80 deposited into the blind hole 45 will only flow as far as the wetting material (e.g., the second conductive layer 54) and will not flow into the vent hole 70. Accordingly, the vent hole 70 will remain open during the filling process and allow any gases and/or fluids trapped in the blind hole 45 to escape.

C. Additional Embodiments of Methods for Depositing Conductive Fill Material

FIGS. 2-3C illustrate several additional embodiments of methods for depositing the fill material into the blind hole 45. FIG. 2, for example, illustrates a method for filling the blind hole 45 using a plating process. This method can include several steps similar to those described above with respect to FIGS. 1A-1E. The subsequent stages of this method, however, may differ from those described above in that the fill material is plated into the blind hole 45 using a bottom-up plating process that selectively fills the blind hole 45 with fill material. In the illustrated embodiment, for example, the substrate 12 can conduct electrical current to the seed layer 50 or other conductive material (e.g., conductive layers 52 and 54) in the blind hole 45. In another embodiment, the conductive layers 52 and 54 may not be deposited onto the seed layer 50. This embodiment continues by applying an electrical potential to the second side 16 of the substrate 12 and an electrode 230 immersed in the plating solution 220. An electrical current accordingly passes through the substrate 12 such that the ions in the plating solution 220 plate onto the seed layer 50 and progressively plate onto each other to fill the blind hole 45 and form an interconnect 282. The plating process can be terminated when the blind hole 45 is either fully or partially filled with the conductive fill material. The workpiece 10 can then undergo further processing as described above in FIGS. 1J and 1K.

FIGS. 3A-3C illustrate another embodiment of stages in a method for filling the blind hole 45 with a conductive fill material. This method can include several steps that are at least generally similar to those described above with respect to FIGS. 1A-1H. The subsequent stages of this method differ from those described above in that a vent hole is not formed through the substrate 12. Instead, the substrate 12 is releasably attached to a support member 310 (e.g., a carrier substrate) that includes a first side 312 and a second side 314 opposite the first side 312. The first side 312 of the support member 310 is releasably attached to the first side 14 of the substrate 12 with an adhesive material 320. The support member 310 has a vent hole 370 substantially aligned with the blind hole 45. The vent hole 370 can be formed either before or after the support member 310 is attached to the substrate 12.

Referring next to FIG. 3B, the second side 16 of the substrate 12 is thinned until the bottom portion of the blind hole 45 is opened. The substrate 12 can be thinned using processes similar to those described above with respect to FIG. 1K. Referring to FIG. 3C, this embodiment continues by depositing a conductive fill material into the blind hole 45 to form an interconnect 382 extending through the substrate 12. The fill material can be solder, copper, or other suitable materials. The fill material can be deposited into the blind hole 45 using a solder wave process, but in other embodiments the fill material can be deposited using plating procedures or other suitable methods.

D. Additional Embodiments of Methods for Forming Vent Holes

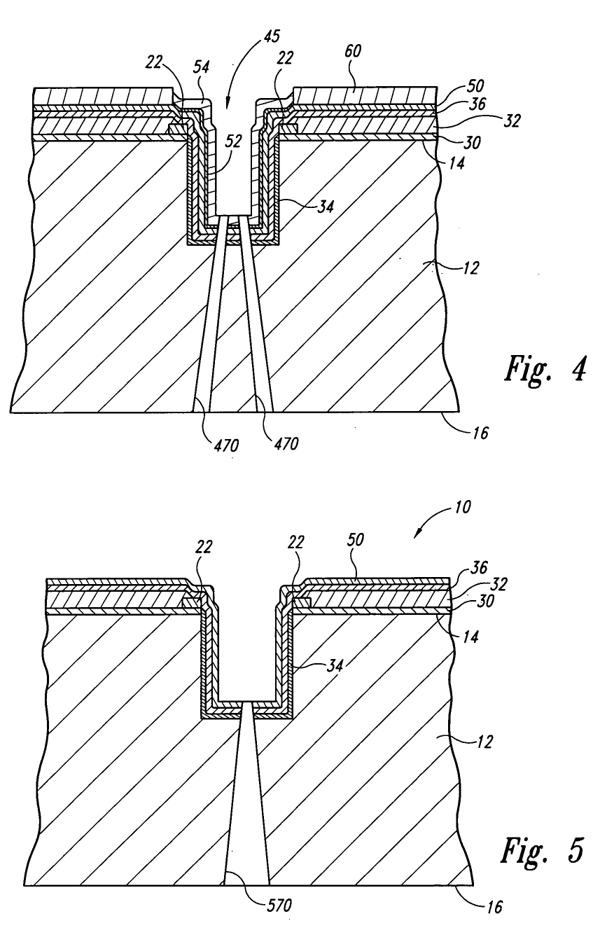

FIG. 4 illustrates a stage in a method for forming an interconnect in a workpiece 410 in accordance with still another embodiment of the invention. Several stages of this method is at least generally similar to those described above with reference to FIGS. 1A-1F. The subsequent stages of this method, however, differ from those described above with reference to FIG. 1G-1K in that a plurality of vent holes 70 are formed for individual blind holes 45. In the illustrated embodiment, for example, two vent holes 470 are formed from the second side 16 of the substrate 12 to the blind hole 45. In other embodiments, more than two vent holes may be formed for each blind hole.

FIG. 5 illustrates a stage in a method for forming an interconnect in a workpiece 510 in accordance with yet another embodiment of the invention. Several stages of this method are at least generally similar to the steps described above with respect to FIGS. 1A-1E. For example, the third dielectric layer 34, the barrier layer 36, and the seed layer 50 can be deposited onto the workpiece 510 to line the blind hole 45. The seed layer 50 can also be enhanced to provide a uniform seed layer. The subsequent stages of this method, however, differ from those described above in that the vent hole 570 is formed after completing the seed layer 50. After forming the vent hole 570, the workpiece 510 can undergo additional processing steps that are at least generally similar to those described above with respect to FIGS. 1F-1K. For example, first and second conductive layer 52 and 54 (FIGS. 1F and 1G) can be deposited into the blind hole 45, and then a fill material can be deposited into the blind hole 45 (FIG. 1I). In other embodiments, the blind hole 45 can be filled without depositing the first and second conductive layer 52 and 54 shown in FIG. 1F and 1G by electrochemically depositing a fill material onto the seed layer. The electrochemical deposition processes can be electroless plating processes or electroplating processes. In the case of electroplating processes, a potential can be applied to the backside of the substrate as shown in FIG. 2, or the potential can be applied directly to the seed layer as known in the art.

From the foregoing, it will be appreciated that specific embodiments of the invention have been described herein for purposes of illustration, but that various modifications may be made without deviating from the spirit and scope of the invention. For example, various aspects of any of the foregoing embodiments can be combined in different combinations. Accordingly, the invention is not limited except as by the appended claims.

I/We claim:

1. A method for manufacturing a microelectronic workpiece having a plurality of microelectronic dies, the individual dies including an integrated circuit and a terminal electrically coupled to the integrated circuit, the method comprising:
forming a blind hole in the workpiece, the blind hole extending from a first exterior side of the workpiece to an intermediate depth in the workpiece;
forming a vent in the workpiece, the vent being in fluid communication with the blind hole; and
constructing an electrically conductive interconnect in at least a portion of the blind hole.

2. The method of claim 1, further comprising removing material from a second exterior side of the workpiece to thin the workpiece.

3. The method of claim 1 wherein forming a blind hole in the workpiece comprises etching a hole into the workpiece such that a portion of the hole is aligned with the terminal and the hole does not extend completely through the workpiece.

4. The method of claim 1 wherein forming a blind hole in the workpiece comprises laser cutting a hole into the workpiece such that a portion of the hole is aligned with the terminal and the hole does not extend completely through the workpiece.

5. The method of claim 1 wherein:
constructing a blind hole in the workpiece comprises etching a hole into the first exterior side such that a portion of the hole is aligned with the terminal and the hole does not extend completely through the workpiece; and
forming a vent comprises laser cutting a hole from the second exterior side to the blind hole.

6. The method of claim 1 wherein forming a vent comprises laser cutting a hole from the second exterior side to the blind hole.

7. The method of claim 1 wherein forming a vent comprises etching and/or mechanically drilling a hole from the second exterior side to the blind hole.

8. The method of claim 1 wherein forming a vent comprises laser cutting a plurality of holes from the second exterior side to the blind hole.

9. The method of claim 1 wherein forming a vent comprises etching and/or mechanically drilling a plurality of holes from the second exterior side to the blind hole.

10. The method of claim 1, further comprising:
depositing a temporary protective filling and/or coating into the blind hole before forming the vent; and
removing the protective filling and/or coating after forming the vent.

11. The method of claim 1 wherein constructing an electrically conductive interconnect comprises filling the blind hole with a conductive fill material to form the interconnect.

12. The method of claim 1 wherein constructing an electrically conductive interconnect comprises filling the blind hole with a conductive fill material to form the interconnect, and wherein the conductive fill material includes Cu, Ni, Co, Ag, Au, solder, or other suitable materials or alloys of materials having the desired conductivity.

13. The method of claim 1 wherein constructing an electrically conductive interconnect comprises plating a conductive fill material into at least a portion of the blind hole.

14. The method of claim 13 wherein plating the conductive fill material into the blind hole comprises applying an electrical potential to the workpiece in the presence of a plating solution.

15. The method of claim 13 wherein plating the conductive fill material into the blind hole comprises electrolessly plating the fill material into the blind hole.

16. The method of claim 1, further comprising:
applying a dielectric liner to at least a portion of the blind hole;
depositing a barrier layer onto the workpiece and into the blind hole over at least a portion of the dielectric liner;
depositing a seed layer onto the workpiece and into the blind hole, wherein the seed layer is over at least a portion of the barrier layer;
applying a layer of resist over the workpiece and forming an opening over the terminal; and
applying a conductive layer into the blind hole and over at least a portion of the seed layer before forming the vent.

17. The method of claim 16, further comprising removing the layer of resist, seed layer, and barrier layer from the at least a portion of the workpiece outside the blind hole after constructing the interconnect and before removing material from a second exterior side of the workpiece to thin the workpiece.

18. The method of claim 16, further comprising enhancing the seed layer before applying the layer of resist.

19. The method of claim 16 wherein the conductive layer is a second conductive layer, and wherein the method further comprises applying a first conductive layer into the blind hole and over the seed layer after applying the layer of resist and before applying the second conductive layer.

20. The method of claim 1, further comprising:
applying a dielectric liner to at least a portion of the blind hole;
depositing a barrier layer onto the workpiece and into the blind hole over at least a portion of the dielectric liner, wherein the barrier layer includes Ta and/or W;
depositing a seed layer onto the workpiece and into the blind hole, the seed layer covering at least a portion of the barrier layer, wherein the seed layer includes Cu;
enhancing the seed layer;
applying a layer of resist over the workpiece and forming an opening over the terminal;
applying a conductive layer into at least a portion of the blind hole using an electroplating process, wherein the conductive layer includes Cu;
applying a wetting agent over at least a portion of the conductive layer using an electroplating process before filling the blind hole with a conductive fill material, wherein the wetting agent includes Ni; and
removing the layer of resist, seed layer, and barrier layer from the at least a portion of the workpiece outside the blind hole after filling the blind hole with a conductive fill material.

21. The method of claim 1, further comprising:
applying a dielectric liner to at least a portion of the blind hole;
depositing a barrier layer onto the workpiece and into the blind hole over at least a portion of the dielectric liner;
depositing a seed layer onto the workpiece and into the blind hole, wherein the seed layer is over at least a portion of the barrier layer;
applying a layer of resist over the workpiece after forming the vent, the layer of resist including an opening over the terminal; and
applying a conductive layer into the blind hole and over at least a portion of the seed layer.

22. A method of manufacturing a microelectronic workpiece, the workpiece including a microelectronic substrate having a first side, a second side opposite the first side, and a plurality of microelectronic dies, the individual dies including an integrated circuit and a plurality of terminals operatively coupled to the integrated circuit, the method comprising:
forming a blind hole in the substrate in alignment with one of the terminals, the blind hole extending from the first side of the substrate to an intermediate depth in the substrate;
forming a vent hole from the second side of the substrate to the blind hole;
constructing an electrically conductive interconnect in at least a portion of the blind hole and in electrical contact with the terminal; and
thinning the substrate from the second side until at least a portion of the interconnect is exposed.

23. The method of claim 22 wherein forming a blind hole in the substrate comprises etching a hole into the substrate such that a portion of the hole is aligned with the terminal and the hole does not extend completely through the substrate.

24. The method of claim 22 wherein forming a blind hole in the substrate comprises laser cutting a hole into the substrate such that a portion of the hole is aligned with the terminal and the hole does not extend completely through the substrate.

25. The method of claim 22 wherein forming a vent hole comprises laser cutting a hole from the second side of the substrate to the blind hole, and wherein the vent hole extends to the blind hole such that gases or other fluids can flow from the blind hole to the vent hole.

26. The method of claim 22 wherein forming a vent hole comprises etching and/or mechanically drilling a hole from the second side of the substrate to the blind hole, and wherein the vent hole extends to the blind hole such that gases or other fluids can flow from the blind hole to the vent hole.

27. The method of claim 22 wherein forming a vent hole comprises laser cutting a plurality of holes from the second side of the substrate to the blind hole.

28. The method of claim 22 wherein forming a vent hole comprises etching and/or mechanically drilling a plurality of holes from the second side of the substrate to the blind hole.

29. The method of claim 22 wherein constructing an electrically conductive interconnect comprises filling the blind hole with a conductive fill material to form the interconnect.

30. The method of claim 22 wherein constructing an electrically conductive interconnect comprises filling the blind hole with a conductive fill material to form the interconnect, and wherein the conductive fill material includes Cu, Ni, Co, Ag, Au, solder, or other suitable materials or alloys of materials having the desired conductivity.

31. The method of claim 22 wherein constructing an electrically conductive interconnect comprises plating a conductive fill material into at least a portion of the blind hole.

32. The method of claim 31 wherein plating the conductive fill material into the blind hole comprises applying an electrical potential to the workpiece in the presence of a plating solution.

33. The method of claim 31 wherein plating the conductive fill material into the blind hole comprises electrolessly plating the fill material into the blind hole.

34. The method of claim 22, further comprising:
applying a dielectric liner to at least a portion of the blind hole;
depositing a barrier layer onto the substrate and into the blind hole over at least a portion of the dielectric liner;
depositing a seed layer onto the substrate and into the blind hole, wherein the seed layer is over at least a portion of the barrier layer;
applying a layer of resist over the substrate and forming an opening over the terminal; and
applying a conductive layer into the blind hole and over at least a portion of the seed layer before forming the vent hole.

35. The method of claim 34, further comprising removing the layer of resist, seed layer, and barrier layer from the at least a portion of the substrate outside the blind hole after constructing the interconnect and before thinning the substrate.

36. The method of claim 34, further comprising enhancing the seed layer before applying the layer of resist.

37. The method of claim 34 wherein the conductive layer is a second conductive layer, and wherein the method further comprises applying a first conductive layer into the blind hole and over the seed layer after applying the layer of resist and before applying the second conductive layer.

38. The method of claim 22, further comprising:
applying a dielectric liner to at least a portion of the blind hole;
depositing a barrier layer onto the substrate and into the blind hole over at least a portion of the dielectric liner, wherein the barrier layer includes Ta and/or W;
depositing a seed layer onto the substrate and into the blind hole, the seed layer covering at least a portion of the barrier layer, wherein the seed layer includes Cu;
enhancing the seed layer;
applying a layer of resist over the substrate and forming an opening over the terminal;
applying a conductive layer into at least a portion of the blind hole using an electroplating process, wherein the conductive layer includes Cu;
applying a wetting agent over at least a portion of the conductive layer using an electroplating process before filling the blind hole with a conductive fill material, wherein the wetting agent includes Ni; and
removing the layer of resist, seed layer, and barrier layer from the at least a portion of the substrate outside the blind hole after filling the blind hole with a conductive material.

39. The method of claim 22, further comprising:
applying a dielectric liner to at least a portion of the blind hole;
depositing a barrier layer onto the substrate and into the blind hole over at least a portion of the dielectric liner;
depositing a seed layer onto the substrate and into the blind hole, wherein the seed layer is over at least a portion of the barrier layer;
applying a layer of resist over the substrate after forming the vent hole, the layer of resist including an opening over the terminal; and
applying a conductive layer into the blind hole and over at least a portion of the seed layer.

40. A method of manufacturing a microelectronic workpiece, the workpiece including a microelectronic substrate having a first side, a second side opposite the first side, and a plurality of microelectronic dies, the individual dies including an integrated circuit and a terminal operatively coupled to the integrated circuit, the method comprising:
forming a blind hole in the substrate in alignment with the terminal, the blind hole extending from the first side of the substrate to an intermediate depth in the substrate;
releasably attaching the first side of the substrate to a support member;
forming a vent hole in the support member such that at least a portion of the vent hole is in fluid communication with the blind hole;
thinning the workpiece from the second side to expose at least a portion of the blind hole such that the blind hole comprises a passage extending completely through the workpiece; and
filling the passage with a conductive fill material to form an interconnect in electrical contact with the terminal.

41. The method of claim 40 wherein forming a blind hole in the substrate comprises etching a hole into the substrate such that a portion of the hole is aligned with the terminal and the hole does not extend completely through the substrate.

42. The method of claim 40 wherein forming a blind hole in the substrate comprises laser cutting a hole into the substrate such that a portion of the hole is aligned with the terminal and the hole does not extend completely through the substrate.

43. The method of claim 40 wherein forming a vent hole in the support member comprises forming a vent hole either before or after releasably attaching the first side of the substrate to the support member.

44. The method of claim 44 wherein filling the passage with a conductive fill material includes filling the passage with Cu, Ni, Co, Ag, Au, solder, or other suitable materials or alloys of materials having the desired conductivity.

45. The method of claim 40 wherein filling the passage with a conductive fill material including filling the passage using a solder wave process.

46. The method of claim 40, further comprising:
applying a dielectric liner to at least a portion of the blind hole depositing a barrier layer onto the substrate and into the blind hole over at least a portion of the dielectric liner;
depositing a seed layer onto the substrate and into the blind hole, wherein the seed layer is over at least a portion of the barrier layer;
applying a layer of resist over the substrate and forming an opening over the terminal; and
applying a conductive layer into the blind hole and over at least a portion of the seed layer before releasably attaching the substrate to the support member.

47. The method of claim 46, further comprising removing the layer of resist, seed layer, and barrier layer from the at least a portion of the substrate outside the blind hole after constructing the interconnect.

48. The method of claim 46, further comprising enhancing the seed layer before applying the layer of resist.

49. The method of claim 46 wherein the conductive layer is a second conductive layer, and wherein the method further comprises applying a first conductive layer into the blind hole and over the seed layer after applying the layer of resist and before applying the second conductive layer.

50. The method of claim 40, further comprising:
applying a dielectric liner to at least a portion of the blind hole;
depositing a barrier layer onto the substrate and into the blind hole over at least a portion of the dielectric liner, wherein the barrier layer includes Ta and/or W;
depositing a seed layer onto the substrate and into the blind hole, the seed layer covering at least a portion of the barrier layer, wherein the seed layer includes Cu;
enhancing the seed layer;
applying a layer of resist over the substrate and forming an opening over the terminal;
applying a conductive layer into at least a portion of the blind hole using an electroplating process, wherein the conductive layer includes Cu;
applying a wetting agent over at least a portion of the conductive layer using an electroplating process before releasably attaching the substrate to the support member, wherein the wetting agent includes Ni; and
removing the layer of resist, seed layer, and barrier layer from the at least a portion of the substrate outside the blind hole after filling the passage with the conductive material.

51. A method of forming an interconnect in electrical contact with a terminal on a microelectronic workpiece, the method comprising:
forming a first opening in a front side of the workpiece in alignment with the terminal, wherein the first opening does not extend completely through the workpiece;
forming a second opening extending from a backside of the workpiece to the first opening, the second opening being in fluid communication with the first opening;
filling the first opening with a conductive fill material; and
removing material from the backside of the workpiece to thin the workpiece and expose at least a portion of the conductive fill material in the first opening.

52. The method of claim 51 wherein forming the first opening comprises etching a blind hole into the workpiece.

53. The method of claim 51 wherein forming the first opening comprises laser cutting a blind hole into the workpiece.

54. The method of claim 51 wherein forming a second opening comprises laser cutting a vent hole from the backside of the workpiece to the first opening.

55. The method of claim 51 wherein forming a second opening comprises etching and/or mechanically drilling a vent hole from the backside of the workpiece to the first opening.

56. The method of claim 51 wherein filling the first opening with a conductive fill material comprises filling the first opening with Cu, Ni, Co, Ag, Au, solder, or other suitable materials or alloys of materials having the desired conductivity.

57. A method of manufacturing a microelectronic workpiece, the workpiece including a substrate having a front side, a backside, and a plurality of microelectronic dies, the individual dies including an integrated circuit and an array of bond-pads electrically coupled to the integrated circuit, the method comprising:
forming a plurality of blind holes in the front side of the substrate and in alignment with corresponding bond-pads, wherein the blind holes do not extend completely through the substrate;
forming a plurality of vent holes in the backside of the substrate, the individual vent holes extending through the substrate to corresponding blind holes;
constructing electrically conductive interconnects in at least a portion of individual blind holes and contacting corresponding bond-pads; and
thinning the workpiece from the backside of the substrate to expose at least a portion of the individual interconnects.

58. A microelectronic assembly, comprising:
a microfeature workpiece including a substrate having a first side, a second side, and a microelectronic die on and/or in the substrate, the die including an integrated circuit and a terminal electrically coupled to the integrated circuit;
a blind hole in the substrate, the blind hole extending from the first side of the substrate to an endpoint at an intermediate depth within the substrate;
a vent hole in the workpiece that is open to the blind hole; and
an electrically conductive interconnect in at least a portion of the blind hole.

59. The assembly of claim 58 wherein the vent hole in the workpiece comprises a hole extending from the second side of the substrate to the blind hole.

60. The assembly of claim 58 wherein the interconnect comprises:
a dielectric liner disposed on the sidewalls of the blind hole and in contact with the substrate;
a barrier layer on the substrate and in the blind hole, the barrier layer being over at least a portion of the dielectric liner;
a seed layer on the substrate and in the blind hole, the seed layer being over at least a portion of the barrier layer;
a layer of resist on the first side of the substrate with an opening over the terminal;
a conductive layer in the blind hole over at least a portion of the seed layer; and
a conductive fill material disposed in the blind hole over at least a portion of the conductive layer and electrically coupled to the terminal.

61. The assembly of claim 58 wherein the interconnect comprises:
a dielectric liner disposed on the sidewalls of the blind hole and in contact with the substrate;
a barrier layer on the substrate and in the blind hole, the barrier layer being over at least a portion of the dielectric liner, wherein the barrier layer includes Ta and/or W;
a seed layer on the substrate and in the blind hole, the seed layer being over at least a portion of the barrier layer, wherein the seed layer includes Cu;
a layer of resist on the first side of the substrate with an opening over the terminal;
a conductive layer in the blind hole over at least a portion of the seed layer, wherein the conductive layer includes Cu;
a wetting agent over at least a portion of the conductive layer, wherein the wetting agent includes Ni; and
a metal fill disposed in the blind hole over at least a portion of the wetting agent and electrically coupled to the terminal.

62. A microelectronic workpiece, comprising:
a substrate having a front side and a backside;
a microelectronic die on and/or in the substrate, the die including an integrated circuit and a terminal electrically coupled to the integrated circuit;
a blind hole in the front side of the substrate and in alignment with the terminal, the blind hole extending through the substrate to an intermediate depth in the substrate between the front side and the backside;
a vent hole in the substrate extending from the backside to the blind hole; and
an electrically conductive interconnect in at least a portion of the blind hole and in contact with the terminal.

63. The workpiece of claim 62 wherein the interconnect comprises:
a dielectric liner disposed on the sidewalls of the blind hole and in contact with the substrate;
a barrier layer on the substrate and in the blind hole, the barrier layer being over at least a portion of the dielectric liner;
a seed layer on the substrate and in the blind hole, the seed layer being over at least a portion of the barrier layer;
a layer of resist on the front side of the substrate with an opening over the terminal;
a conductive layer in the blind hole over at least a portion of the seed layer; and
a conductive fill material disposed in the blind hole over at least a portion of the conductive layer and electrically coupled to the terminal.

64. The workpiece of claim 62 wherein the interconnect comprises:
a dielectric liner disposed on the sidewalls of the blind hole and in contact with the substrate;
a barrier layer on the substrate and in the blind hole, the barrier layer being over at least a portion of the dielectric liner, wherein the barrier layer includes Ta and/or W;
a seed layer on the substrate and in the blind hole, the seed layer being over at least a portion of the barrier layer, wherein the seed layer includes Cu;
a layer of resist on the front side of the substrate with an opening over the terminal;
a conductive layer in the blind hole over at least a portion of the seed layer, wherein the conductive layer includes Cu;
a wetting agent over at least a portion of the conductive layer, wherein the wetting agent includes Ni; and
a metal fill disposed in the blind hole over at least a portion of the wetting agent and electrically coupled to the terminal.
